(19) United States
(12) Patent Application Publication
(10) Pub. No.: US 2019/0237709 A1
(43) Pub. Date: Aug. 1, 2019

(54) ELECTROLUMINESCENT DEVICE, METHOD OF MANUFACTURING THE SAME AND DISPLAY DEVICE

(71) Applicants: BOE Technology Group Co., Ltd., Beijing (CN); Ordos Yuansheng Optoelectronics Co., Ltd., Inner Mongolia (CN)

(72) Inventor: Kening Zheng, Beijing (CN)

(21) Appl. No.: 16/123,296

(22) Filed: Sep. 6, 2018

(30) Foreign Application Priority Data
Jan. 31, 2018 (CN) 201810097377.1

(51) Int. Cl. H01L 51/56; H01L 51/52; H01L 51/50; H01L 51/00; C09K 11/06

(52) U.S. Cl. CPC H01L 51/56; H01L 51/5206; H01L 51/5221; H01L 51/502; H01L 51/5056; C09K 11/06; H01L 51/5092; H01L 51/5096; H01L 51/5275; H01L 51/001; H01L 51/5072

(57) ABSTRACT

An electroluminescent device, a method of manufacturing the electroluminescent device and a display panel are provided. The electroluminescent device includes a first electrode; a second electrode; a light emitting layer between the first electrode and the second electrode; and a light extraction layer on a side of the second electrode facing away from the light emitting layer. The light extraction layer includes a photoresponsive material such that an optical property of the light extraction layer is variable.

### CROSS-REFERENCE TO RELATED APPLICATION

This application claims priority to Chinese Patent Application No. 201810097377.1 filed on Jan. 31, 2018 in the State Intellectual Property Office of China, the disclosure of which is hereby incorporated by reference in its entirety.

### TECHNICAL FIELD

The present disclosure relates to the field of display technologies, and in particular, to an electroluminescent device, a method of manufacturing the electroluminescent device and a display panel.

### DESCRIPTION OF THE RELATED ART

Currently, displays using electroluminescent devices such as organic light emitting diodes or quantum dot light emitting diodes as light emitting units generally have problems of poor luminous efficiency and low brightness.

### SUMMARY

An embodiment of the present disclosure provides an electroluminescent device comprising: a first electrode; a second electrode; a light emitting layer between the first electrode and the second electrode; and a light extraction layer on a side of the second electrode facing away from the light emitting layer, wherein the light extraction layer comprises a photoresponsive material such that an optical property of the light extraction layer is variable.

In some embodiments, a light refractive index of the light extraction layer is increased in response to irradiation of an external light, and is restored to an original state in response to an absence of the irradiation of the external light.

In some embodiments, the photoresponsive material comprises a cis isomer and a trans isomer, at least a portion of the cis isomer is converted into the trans isomer in response to the irradiation of the external light, and a light refractive index of the trans isomer is greater than a light refractive index of the cis isomer.

In some embodiments, the trans isomer formed by converting the at least a portion of the cis isomer is restored to the cis isomer in response to the absence of the irradiation of the external light.

In some embodiments, the light refractive index of the light extraction layer depends on a ratio of the cis isomer to the trans isomer in the photoresponsive material.

In some embodiments, an amount by which the light refractive index of the light extraction layer is increased in response to the irradiation of the external light depends on an ability of the cis isomer to be converted into the trans isomer in the photoresponsive material.

In some embodiments, the light extraction layer further comprises a light extraction layer body material, the light extraction layer body material being doped with the photoresponsive material.

In some embodiments, a doping mass ratio of the photoresponsive material to the light extraction layer body material depends on at least one of a ratio of the cis isomer to the trans isomer in the photoresponsive material and an ability of the cis isomer to be converted into the trans isomer in the photoresponsive material.

In some embodiments, the photoresponsive material comprises a conjugated compound having a carbon-carbon double bond, a carbon-nitrogen double bond or a nitrogen-nitrogen double bond.

In some embodiments, the conjugated compound comprises azobenzene or polyvinyl carbazole.

In some embodiments, the electroluminescent device comprises an organic light emitting diode, a polymer light emitting diode or a quantum dot light emitting diode.

An embodiment of the present disclosure provides a display panel comprising a plurality of electroluminescent devices according to the above embodiments arranged in an array.

An embodiment of the present disclosure provides a method of manufacturing an electroluminescent device, comprising: providing a first electrode; forming a light emitting layer and a second electrode on the first electrode in sequence; and forming a light extraction layer on the second electrode, wherein the light extraction layer comprises a photoresponsive material such that an optical property of the light extraction layer is variable.

In some embodiments, the forming the light extraction layer on the second electrode comprises: forming the light extraction layer on the second electrode by vacuum evaporation.

In some embodiments, the forming the light extraction layer on the second electrode by vacuum evaporation comprises: placing the photoresponsive material in an evaporating crucible; and heating the evaporating crucible in a vacuum.

In some embodiments, the light extraction layer further comprises a light extraction layer body material, wherein the forming the light extraction layer on the second electrode by vacuum evaporation comprises: placing the photoresponsive material and the light extraction layer body material in different evaporating crucibles; and heating the different evaporating crucibles in a vacuum, and controlling a doping mass ratio of the photoresponsive material to the light extraction layer body material by adjusting evaporation rates in the different evaporating crucibles.

In some embodiments, the light extraction layer further comprises a light extraction layer body material, wherein the forming the light extraction layer on the second electrode by vacuum evaporation comprises: mixing the photoresponsive material and the light extraction layer body material in an evaporating crucible with a predetermined doping mass ratio; and heating the evaporating crucible in a vacuum.

In some embodiments, the forming the light extraction layer on the second electrode comprises: forming the light extraction layer on the second electrode by coating or deposition.

In some embodiments, the light extraction layer further comprises a light extraction layer body material, wherein the forming the light extraction layer on the second electrode comprises: mixing the photoresponsive material and the light extraction layer body material with a predetermined doping mass ratio to form a solid mixture; and depositing the solid mixture on the second electrode.

In some embodiments, the light extraction layer further comprises a light extraction layer body material, wherein the forming the light extraction layer on the second electrode comprises: mixing and dissolving the photoresponsive material and the light extraction layer body material with a predetermined doping mass ratio to form a liquid mixture; and coating the second electrode with the liquid mixture.

### BRIEF DESCRIPTION OF THE DRAWINGS

FIG. 1 is a schematic structural view of an electroluminescent device according to an embodiment of the present disclosure;

FIG. 2 is a flow chart of a method of manufacturing an electroluminescent device according to an embodiment of the present disclosure;

FIG. 3 is a flow chart of forming a light extraction layer according to an embodiment of the present disclosure;

FIG. 4 is a flow chart of forming a light extraction layer according to an embodiment of the present disclosure;

FIG. 5 is a flowchart of forming a light extraction layer according to an embodiment of the present disclosure;

FIG. 6 is a flowchart of forming a light extraction layer according to an embodiment of the present disclosure; and

FIG. 7 is a flow chart of forming a light extraction layer according to an embodiment of the present disclosure.

### DETAILED DESCRIPTION OF THE EMBODIMENTS

The specific examples of an electroluminescent device, a manufacturing method thereof and a display panel provided by the embodiments of the present disclosure are described in detail below with reference to the accompanying drawings. It should be noted that the embodiments described in the present specification are merely a part of the embodiments of the present disclosure, and not all of the embodiments, and the features in the embodiments and the embodiments in the present disclosure may be combined with each other without conflict. In addition, all other embodiments obtained by those skilled in the art based on the embodiments of the present disclosure without creative efforts are within the scope of the present disclosure.

In the related art, a light extraction layer is added on a semitransparent electrode (e.g., a cathode) of an electroluminescent device so as to weaken a waveguide effect of light emitted by a light emitting layer and improve light emission rate. Even so, the inventors have found that when the display using the electroluminescent device as the light emitting unit is used in a strong light environment such as outdoors or the like, the external light is too bright, and the display brightness is low, resulting in poor display performance, so that it is not conducive to human eyes. In the case, the brightness of the display may only be increased by increasing the driving voltage difference of the light emitting unit, however this will increase the power consumption of the display and shorten the standby time.

In the related art, the electroluminescent device generally includes an anode, a hole injection layer, a hole transport layer, an electron blocking layer, a light emitting layer, a hole blocking layer, an electron transport layer, an electron injection layer, a cathode and a light extraction layer which are sequentially stacked. The light extraction layer may be made of an inorganic material such as magnesium fluoride (MgF₂), magnesium oxide (MgO), zinc oxide (ZnO) or silicon dioxide (SiO₂) or the like, or made of an organic material such as 3-hydroxyquinoline aluminum (Alq₃) or fluorene polymer or the like. A light refractive index of the light extraction layer is fixed and not varied.

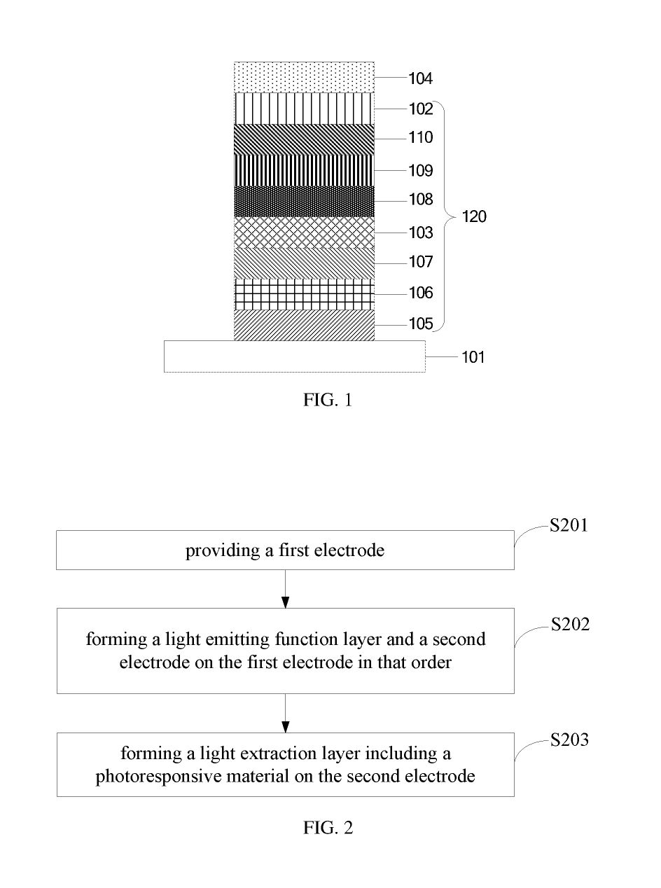

An embodiment of the present disclosure provides an electroluminescent device. FIG. 1 is a schematic structural view of an electroluminescent device according to an embodiment of the present disclosure. As shown in FIG. 1, the electroluminescent device includes a first electrode 101 such as an anode, a light emitting function layer 120, a second electrode 102 such as a cathode, and a light extraction layer 104 which are sequentially stacked. The light emitting function layer 120 is disposed between the first electrode 101 and the second electrode 102, and includes a hole injection layer 105, a hole transport layer 106, an electron blocking layer 107, a light emitting layer 103, a hole blocking layer 108, an electron transport layer 109, and an electron injection layer 110 which are sequentially stacked in a direction from the first electrode 101 toward the second electrode 102. The light extraction layer 104 is located on a side of the second electrode 102 facing away from the first electrode 101 and includes a photoresponsive material. The photoresponsive material includes a cis isomer and a trans isomer, and a light refractive index of the trans isomer is greater than a light refractive index of the cis isomer. In an absence of the irradiation of an external light, the photoresponsive material is in a relatively stable state, in which the ratio of the cis isomer to the trans isomer is fixed. The light refractive index of the light extraction layer depends on the ratio of the cis isomer to the trans isomer in the photoresponsive material. The cis isomer of the photoresponsive material is not stable, and at least a portion of the cis isomer is readily isomerized into the trans isomer under irradiation of the external light, such as light having a specific wavelength. The light refractive index of the trans isomer is greater than the light refractive index of the cis isomer, so that the light refractive index of the photoresponsive material as a whole is increased. As a result, the light refractive index of the light extraction layer 104 including the photoresponsive material is also increased. The amount of the cis isomer isomerized into the trans isomer is related to the intensity of the external light, the stronger the intensity of the external light is, the larger the amount of the cis isomer isomerized into the trans isomer is, and the greater the light refractive index of the light extraction layer 104 including the photoresponsive material is. That is, an amount by which the light refractive index of the light extraction layer is increased in response to the irradiation of external light depends on an ability of the cis isomer in the photoresponsive material to be isomerized to the trans isomer.

In an embodiment, the light having a specific wavelength is, for example, ultraviolet light. The higher a light refractive index of a medium is, the stronger an ability of the medium to refract incident light is. Therefore, when the light emitted from the light emitting layer 103 is incident on an interface between the second electrode 102 and the light extraction layer 104 via the second electrode 102, as the light refractive index of the light extraction layer 104 increases, the refracted light is increased and the reflected light is reduced, so that more light is emitted from the light extraction layer 104 through refraction, thereby increasing the light emission rate and improving the luminous efficiency. In this way, in an outdoor environment or other strong light environment, the light refractive index of the light extraction layer 104 is increased, so that more light may be emitted from the electroluminescent device, thereby effectively increasing the light emission rate and enhancing the display brightness. Therefore, it is not necessary to enhance the brightness of the display device by increasing a driving voltage difference of the electroluminescent device, so that standby time is not affected. In an absence of the irradiation of the external light, the trans isomer which is formed by isomerizing the cis isomer in the photoresponsive material is restored to the cis isomer. At this time, the light refractive index of the light extraction layer 104 is restored to the light refractive index in the absence of irradiation of the external light.

It should be noted that the light extraction layer 104 including the photoresponsive material in the electroluminescent device provided by the present disclosure may or may not be electrically conductive. Specifically, if the light extraction layer 104 is not electrically conductive, the second electrode 102 may be directly connected to an external circuit by wires or other means in a process of driving the electroluminescent device to emit light. If the light extraction layer 104 is electrically conductive, in the process of driving the electroluminescent device to emit light, the second electrode 102 may be directly connected to the external circuit by wires or other means, alternatively, the external circuit may be connected to the light extraction layer 104 by wires or other means, thereby indirectly electrically connecting the second electrode 102 to the external circuit.

Also, one of the first electrode 101 and the second electrode 102 serves as an anode and the other serves as a cathode. Specifically, in the embodiment illustrated in FIG. 1, the first electrode 101 serves as an anode and the second electrode 102 serves as a cathode. The light emitting layer 103 may be a color light emitting layer or a white light emitting layer. If the light emitting layer 103 is a white light emitting layer, color display may be realized by providing a color filter on a light emitting surface of the electroluminescence device. The light emitting layer 103 may be made of an organic small molecule material, an organic polymer material or a quantum dot material. If the light emitting layer 103 is made of the organic small molecule material, the electroluminescent device is an organic light emitting diode (abbreviated as OLED). if the light emitting layer 103 is made of the organic polymer material, the electroluminescent device is a polymer light emitting diode (abbreviated as PLED). If the light emitting layer 103 is made of the quantum dot material, the electroluminescent device is a quantum dot light emitting diode (abbreviated as QLED).

In the related art, the light refractive index of the light extraction layer is not changeable, so that in a strong light environment such as outdoors or the like, it is necessary to enhance the display brightness by increasing the driving voltage difference of the electroluminescent device. As a result, the energy consumption is large, and the standby time is reduced. In order to ensure the standby time, in the embodiments of the present disclosure, the light extraction layer 104 having an increased light refractive index under irradiation can be manufactured by using the photoresponsive material. Therefore, in a strong light environment such as outdoors or the like, the display brightness may be enhanced and the standby time is not affected without increasing the driving voltage difference of the electroluminescent device.

In an embodiment, the light extraction layer 104 may further include a light extraction layer body material, and the light extraction layer 104 having a single layer structure may be obtained by doping the light extraction layer body material with the photoresponsive material.

Specifically, as shown in FIG. 1, in the light extraction layer 104 having the single layer structure obtained by doping the light extraction layer body material with the photoresponsive material, since the photoresponsive material may be irradiated by the external light, at least a portion of the cis isomer in the photoresponsive material is converted into the trans isomer under irradiation, such that the light refractive index of the light extraction layer 104 is increased, and more light may be emitted from the electroluminescent device. Therefore, the light emission rate is effectively improved, and the brightness is increased. In this way, it is not necessary to enhance the display brightness of the display device by increasing the driving voltage difference of the electroluminescent device, and the standby time is ensured.

In the above electroluminescent devices provided by the embodiments of the present disclosure, a doping mass ratio of the photoresponsive material to the light extraction layer body material depends on a ratio of the trans isomer to the cis isomer in the photoresponsive material. Alternatively, the doping mass ratio of the photoresponsive material to the light extraction layer body material depends on an ability of the cis isomer in the photoresponsive material to be converted into the trans isomer. Alternatively, the doping mass ratio of the photoresponsive material to the light extraction layer body material depends on both the ratio of the trans isomer to the cis isomer in the photoresponsive material and the ability of the cis isomer in the photoresponsive material to be converted into the trans isomer.

For example, for two same light extraction layer body materials, one is doped with the photoresponsive material A to form the light extraction layer 104, and the other is doped with the photoresponsive material B to form the light extraction layer 104. Assuming that the ratio of the trans isomer to the cis isomer in the photoresponsive material A is smaller than the ratio of the trans isomer to the cis isomer in the photoresponsive material B. Under the same condition, in order to make an increased amount of light emitted by the light extraction layer including the photoresponsive material A be equal to an increased amount of light emitted by the light extraction layer including the light corresponding material B, the mass of the photoresponsive material A with which the light extraction layer body material is doped may be less than the mass of the photoresponsive material B with which the light extraction layer body material is doped; alternatively, the cis isomer in the photoresponsive material A is more easily converted into the trans isomer than that in the photoresponsive material B; alternatively, the mass of the photoresponsive material A with which the light extraction layer body material is doped may be less than the mass of the photoresponsive material B with which the light extraction layer body material is doped and the cis isomer in the photoresponsive material A is more easily converted into the trans isomer than that in the photoresponsive material B. In the specific implementation, the doping mass ratio of the photoresponsive material to the light extraction layer body material may be flexibly set according to actual conditions, and is not limited to the doping manners described above.

It should be noted that, in the above electroluminescent device, the material of the light extraction layer may be an inorganic material such as magnesium fluoride (MgF₂), magnesium oxide (MgO), zinc oxide (ZnO) or silicon dioxide (SiO₂) or the like, or may be an organic material such as 3-hydroxyquinoline aluminum (Alq₃) or fluorene polymer or the like, which is not specifically limited herein. The photoresponsive material may be a conjugated polymer having a carbon-carbon double bond, a carbon-nitrogen double bond or a nitrogen-nitrogen double bond, and such the conjugated polymer undergoes reversible cis-trans isomerism under the action of the external light. Specifically, the conjugated polymer may be, for example, azobenzene having a nitrogen-nitrogen double bond or polyvinyl carbazole having a carbon-carbon double bond. In the specific implementation, other conjugated polymer such as azobenzene derivative and the like may also be selected. The conjugated polymer is not limited herein.

An embodiment of the present disclosure provides a method of manufacturing an electroluminescent device, and FIG. 2 is a flow chart of a method of manufacturing an electroluminescent device according to an embodiment of the present disclosure. As shown in FIG. 2, the method of manufacturing the electroluminescent device may specifically include the following steps:

S201: providing a first electrode;

S202: forming a light emitting function layer and a second electrode on the first electrode in that order;

S203: forming a light extraction layer including a photoresponsive material on the second electrode.

In step S202, the light emitting function layer includes a hole injection layer, a hole transport layer, an electron blocking layer, a light emitting layer, a hole blocking layer, an electron transport layer, and an electron injection layer which are sequentially formed.

In step S203, the light extraction layer may be formed on the second electrode by vacuum evaporation, deposition, coating such as spin coating, or inkjet printing.

The photoresponsive material includes a cis isomer and a trans isomer such that an optical property of the light extraction layer may be varied in response to an external light. Under irradiation of the external light, the cis isomer in the photoresponsive material may be converted into the trans isomer so as to increase the light refractive index of the light extraction layer, thereby increasing the amount of light extraction and enhancing the display brightness. In this way, it is not necessary to enhance the brightness of the display device by increasing a driving voltage difference of the electroluminescent device, and standby time is not affected.

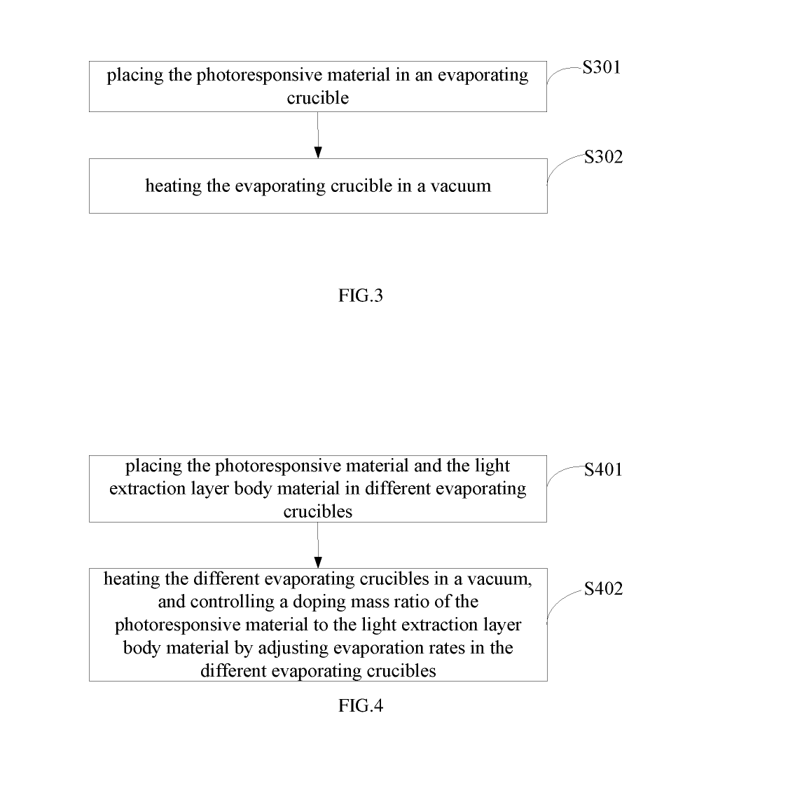

In an embodiment, the light extraction layer may be only made of the photoresponsive material. The step of forming the light extraction layer by vacuum evaporation is as shown in FIG. 3 and includes:

S301: placing the photoresponsive material in an evaporating crucible;

S302: heating the evaporating crucible in a vacuum.

In an embodiment, the light extraction layer 104 is composed of the photoresponsive material and a light extraction layer body material. Since the light extraction layer 104 is made of the photoresponsive material and the light extraction layer body material, an actual fabrication process of the electroluminescent device involves processes such as doping, evaporation and the like, and there may be many processes.

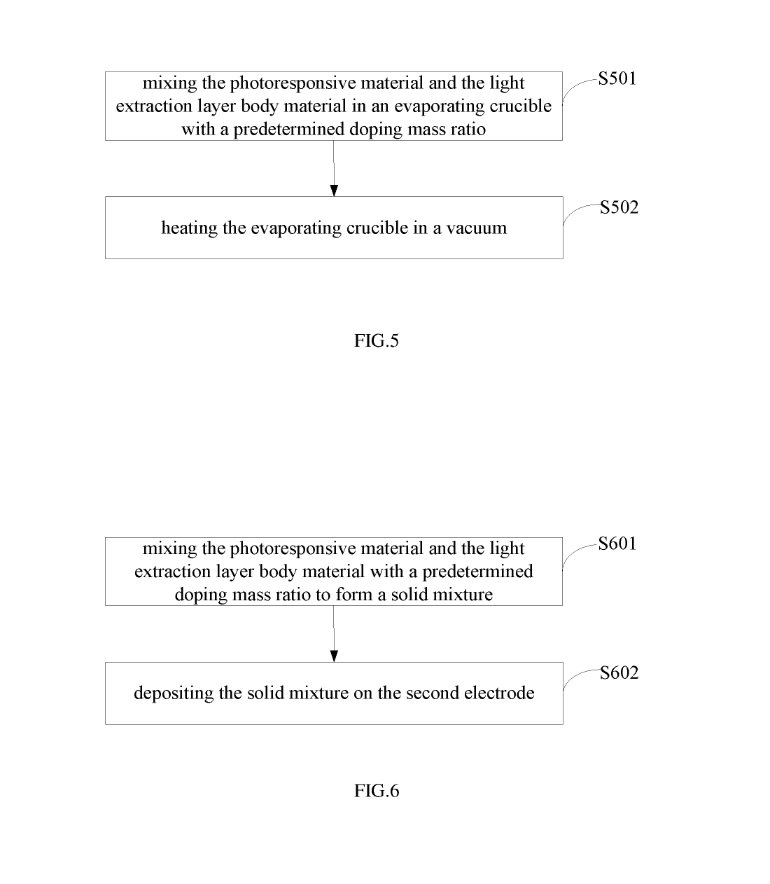

In an embodiment, as shown in FIG. 4, the step of forming the light extraction layer including the light extraction layer body material and the photoresponsive material on the second electrode by vacuum evaporation includes:

S401: placing the photoresponsive material and the light extraction layer body material in different evaporating crucibles;

S402: heating the different evaporating crucibles in a vacuum, and controlling a doping mass ratio of the photoresponsive material to the light extraction layer body material by adjusting evaporation rates in the different evaporating crucibles.

In an alternative embodiment, as shown in FIG. 5, the step of forming the light extraction layer including the light extraction layer body material and the photoresponsive material on the second electrode by vacuum evaporation includes:

S501: mixing the photoresponsive material and the light extraction layer body material in an evaporating crucible with a predetermined doping mass ratio;

S502: heating the evaporating crucible in a vacuum.

In this way, the light extraction layer is formed by evaporating a solid mixture of the photoresponsive material and the light extraction layer body material onto the second electrode.

In an embodiment, as shown in FIG. 6, the step of forming the light extraction layer including the light extraction layer body material and the photoresponsive material on the second electrode by deposition includes:

S601: mixing the photoresponsive material and the light extraction layer body material with a predetermined doping mass ratio to form a solid mixture;

S602: depositing the solid mixture on the second electrode.

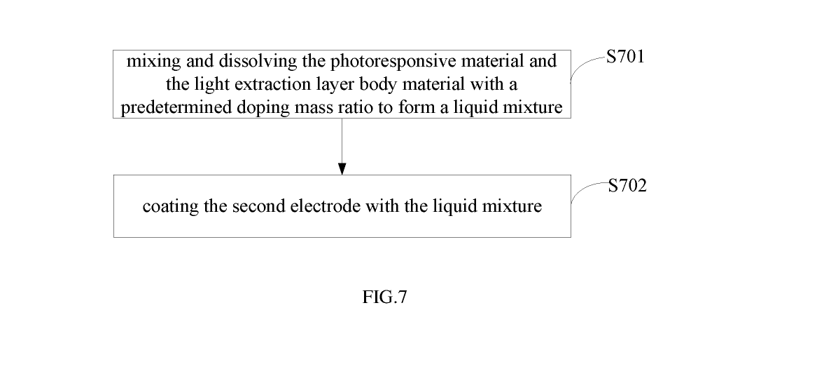

In an embodiment, as shown in FIG. 7, the step of forming the light extraction layer including the light extraction layer body material and the photoresponsive material on the second electrode by coating includes:

S701: mixing and dissolving the photoresponsive material and the light extraction layer body material with a predetermined doping mass ratio to form a liquid mixture;

S702: coating the second electrode with the liquid mixture.

In step S701, the photoresponsive material and the light extraction layer body material may be firstly mixed into a solid mixture and then dissolved, alternatively, the photoresponsive material and the light extraction layer body material may be firstly dissolved respectively and then mixed.

An embodiment of the present disclosure provides a display panel. The display panel includes a plurality of the electroluminescent devices in the above embodiments, and the plurality of electroluminescent devices are arranged in an array in the display panel

An embodiment of the present disclosure provides a display device including the display panel in the above embodiment. For example, the display device is any product or component having a display function, such as a tablet, a television, a display, a notebook computer, a digital photo frame, a navigator and the like, which is not limited in the disclosure.

Since the principle of solving the problem by the display panel and the display device is similar to the principle of solving the problem by the above electroluminescent device, the display panel and the display device provided by the embodiment of the present disclosure may be implemented by referring to the implementation of the above-mentioned electroluminescent device provided by the embodiment of the present disclosure. The repetition will be omitted. In addition, other indispensable components of the display panel and the display device are well known to those of ordinary skill in the art, and are not described herein, they should not be construed as limiting the disclosure.

In the above electroluminescent device and display panel provided by the embodiments of the present disclosure, the electroluminescent device includes a first electrode, a second electrode, a light emitting function layer between the first electrode and the second electrode, and a light extraction layer on a side of the second electrode away from the light emitting function layer. The light extraction layer includes a photoresponsive material such that an optical property of the light extraction layer may be changed in response to an external light. Since the cis isomer in the photoresponsive material is easily converted into the trans isomer under irradiation of the external light, and the light refractive index of the trans isomer of the photoresponsive material is greater than the light refractive index of the cis isomer, the light refractive index of the photoresponsive material is increased under irradiation of the external light, so that the light refractive index of the light extraction layer containing the photoresponsive material is also increased. In this way, more light may be emitted from the electroluminescent device, thereby effectively increasing the light emission rate. Therefore, when used in a strong light environment such as outdoors or the like, the brightness of the display device having the electroluminescent device may be enhanced without increasing the driving voltage difference of the electroluminescent device, and there is no increase in power consumption and no impact on standby time.

It will be apparent to those skilled in the art that various modifications and variations may be made in the present disclosure without departing from the spirit and scope of the disclosure. Thus, if such modifications and variations of the present disclosure are within the scope of the appended claims and their equivalents, the present disclosure is intended to include such modifications and variations.

What is claimed is:

1. An electroluminescent device comprising:
a first electrode;
a second electrode;
a light emitting layer between the first electrode and the second electrode; and
a light extraction layer on a side of the second electrode facing away from the light emitting layer,
wherein the light extraction layer comprises a photoresponsive material such that an optical property of the light extraction layer is variable.

2. The electroluminescent device according to claim 1, wherein a light refractive index of the light extraction layer is increased in response to irradiation of an external light, and is restored to an original state in response to an absence of the irradiation of the external light.

3. The electroluminescent device according to claim 2, wherein the photoresponsive material comprises a cis isomer and a trans isomer, at least a portion of the cis isomer is converted into the trans isomer in response to the irradiation of the external light, and a light refractive index of the trans isomer is greater than a light refractive index of the cis isomer.

4. The electroluminescent device according to claim 3, wherein the trans isomer formed by converting the at least a portion of the cis isomer is restored to the cis isomer in response to the absence of the irradiation of the external light.

5. The electroluminescent device according to claim 4, wherein the light refractive index of the light extraction layer depends on a ratio of the cis isomer to the trans isomer in the photoresponsive material.

6. The electroluminescent device according to claim 4, wherein an amount by which the light refractive index of the light extraction layer is increased in response to the irradiation of the external light depends on an ability of the cis isomer to be converted into the trans isomer in the photoresponsive material.

7. The electroluminescent device according to claim 1, wherein the light extraction layer further comprises a light extraction layer body material, the light extraction layer body material being doped with the photoresponsive material.

8. The electroluminescent device according to claim 7, wherein a doping mass ratio of the photoresponsive material to the light extraction layer body material depends on at least one of a ratio of the cis isomer to the trans isomer in the photoresponsive material and an ability of the cis isomer to be converted into the trans isomer in the photoresponsive material.

9. The electroluminescent device according to claim 1, wherein the photoresponsive material comprises a conjugated compound having a carbon-carbon double bond, a carbon-nitrogen double bond or a nitrogen-nitrogen double bond.

10. The electroluminescent device according to claim 9, wherein the conjugated compound comprises azobenzene or polyvinyl carbazole.

11. The electroluminescent device according to claim 1, wherein the electroluminescent device comprises an organic light emitting diode, a polymer light emitting diode or a quantum dot light emitting diode.

12. A display panel comprising a plurality of electroluminescent devices according to claim 1 arranged in an array.

13. A method of manufacturing an electroluminescent device, comprising:
providing a first electrode;
forming a light emitting layer and a second electrode on the first electrode in sequence; and
forming a light extraction layer on the second electrode,
wherein the light extraction layer comprises a photoresponsive material such that an optical property of the light extraction layer is variable.

14. The method according to claim 13, wherein the forming the light extraction layer on the second electrode comprises:
forming the light extraction layer on the second electrode by vacuum evaporation.

15. The method according to claim 14, wherein the forming the light extraction layer on the second electrode by vacuum evaporation comprises:
placing the photoresponsive material in an evaporating crucible; and
heating the evaporating crucible in a vacuum.

16. The method according to claim 14, wherein the light extraction layer further comprises a light extraction layer body material,
wherein the forming the light extraction layer on the second electrode by vacuum evaporation comprises:
placing the photoresponsive material and the light extraction layer body material in different evaporating crucibles; and
heating the different evaporating crucibles in a vacuum, and controlling a doping mass ratio of the photoresponsive material to the light extraction layer body material by adjusting evaporation rates in the different evaporating crucibles.

17. The method according to claim 14, wherein the light extraction layer further comprises a light extraction layer body material,
wherein the forming the light extraction layer on the second electrode by vacuum evaporation comprises:
mixing the photoresponsive material and the light extraction layer body material in an evaporating crucible with a predetermined doping mass ratio; and
heating the evaporating crucible in a vacuum.

18. The method according to claim 13, wherein the forming the light extraction layer on the second electrode comprises:
forming the light extraction layer on the second electrode by coating or deposition.

19. The method according to claim 18, wherein the light extraction layer further comprises a light extraction layer body material,
wherein the forming the light extraction layer on the second electrode comprises:
mixing the photoresponsive material and the light extraction layer body material with a predetermined doping mass ratio to form a solid mixture; and
depositing the solid mixture on the second electrode.

20. The method according to claim 18, wherein the light extraction layer further comprises a light extraction layer body material,
wherein the forming the light extraction layer on the second electrode comprises:
mixing and dissolving the photoresponsive material and the light extraction layer body material with a predetermined doping mass ratio to form a liquid mixture; and
coating the second electrode with the liquid mixture.
